(19) United States
(12) Patent Application Publication
(10) Pub. No.: US 2015/0247232 A1
(43) Pub. Date: Sep. 3, 2015

(54) Tuning the Piezoelectric Coefficient of a Doped Piezoelectric Material Using Multiple Noble Gases

(71) Applicant: Avago Technologies General IP (Singapore) Pte. Ltd, Singapore (SG)

(72) Inventors: Phil Nikkel, Loveland, CO (US); Chris Feng, Fort Collins, CO (US)

(73) Assignee: Avago Technologies General IP (Singapore) Pte. Ltd, Singapore (SG)

(21) Appl. No.: 14/193,191

(22) Filed: Feb. 28, 2014

(51) Int. Cl. C23C 14/06; C23C 14/34

(52) U.S. Cl. CPC C23C 14/0641; C23C 14/34

(57) ABSTRACT

A process chamber is provided. A target comprising an alloy comprising a base metal atomic species and an alloy atomic species is placed in the process chamber. The concentration of the alloy atomic species is subject to a manufacturing variation. A substrate is placed in the process chamber. While supplying gases comprising a noble gas of a first atomic species and a noble gas of a second atomic species, different from the first atomic species, to the process chamber, a sputtering operation is performed to transfer target material from the target to the substrate to form a piezoelectric film. A relative flow rate is set between the noble gas of the first atomic species and the noble gas of the second atomic species to form the film with a predetermined piezoelectric coefficient notwithstanding the manufacturing variation.

### BACKGROUND

Diplexers fabricated using film bulk acoustic resonators (FBARs) are a component of large numbers of cell phones and smartphones. An FBAR is an electroacoustic device composed of a thin film of piezoelectric material sandwiched between two electrodes. The electrical properties of the constituent FBARs determine the RF properties, e.g., pass frequency and block frequency, of the diplexer. The electrical properties of the FBARs are determined by the piezoelectric coefficient of the piezoelectric material of the FBAR. The piezoelectric material includes a dopant that controls the piezoelectric coefficient of the piezoelectric material. The piezoelectric coefficient depends on the concentration of the dopant in the piezoelectric material. Therefore, control of the concentration of the dopant in the piezoelectric material is needed to produce a high yield of diplexers with RF properties that meet a given specification.

The piezoelectric material of some FBARs is aluminum nitride (AlN) doped with less than 10% of scandium (Sc). The concentration of scandium in the piezoelectric material determines the piezoelectric coefficient of the piezoelectric material and, hence, the RF properties of diplexers fabricated using the FBARs. When the FBARs are fabricated, a film of doped aluminum nitride is deposited over an electrode pattern by sputtering from a target that is an alloy of aluminum and scandium. The sputtering is performed in an atmosphere containing nitrogen and a single noble gas, typically argon (Ar). The concentration of scandium in the deposited piezoelectric material depends on the concentration of scandium in the target material. During manufacture of targets, due to natural manufacturing processing variation, varying amounts of scandium are contained in the target material of each target. The resulting manufacturing variations in the concentration of scandium in the target material of current commercially-manufactured targets impair the yield of diplexers with RF properties that meet the specification.

Accordingly, what is needed is a way to sputter deposit doped piezoelectric material with a consistent piezoelectric coefficient notwithstanding the manufacturing variations in the concentration of the dopant in the target material.

### BRIEF DESCRIPTION OF THE DRAWINGS

FIG. 1 is a schematic drawing showing an example of a physical vapor deposition (PVD) system that can be used to perform the sputter deposition method disclosed herein.

FIG. 2 is a chart showing examples of percentage differences between the piezoelectric coefficients of doped aluminum nitride films conventionally deposited using six exemplary targets and a nominal piezoelectric coefficient.

FIG. 3 is a chart showing an example of a range of percentage differences between piezoelectric coefficients of doped aluminum nitride films and a nominal piezoelectric coefficient that can be obtained by varying the relative flow rate between two noble gases in the sputter deposition method disclosed herein.

FIG. 4 is a flowchart showing an example of a method as disclosed herein for sputter depositing a doped piezoelectric film on a substrate.

### DETAILED DESCRIPTION

A method of sputter depositing a doped piezoelectric film on a substrate is disclosed herein. In the method, a process chamber is provided, and a target is placed in the process chamber. The target comprises an alloy that comprises a base metal atomic species and an alloy atomic species, in which the concentration of the alloy atomic species in the alloy is subject to a manufacturing variation. The substrate is placed in the process chamber. Then, while supplying gases comprising a noble gas of a first atomic species and a noble gas of a second atomic species, different from the first atomic species, to the process chamber, a sputtering operation is performed to transfer target material from the target to the substrate to form the film. A relative flow rate is set between the noble gas of the first atomic species and the noble gas of the second atomic species to form the film with a predetermined piezoelectric coefficient notwithstanding the manufacturing variation in the concentration of the alloy atomic species in the alloy.

Also disclosed herein is a method of sputter depositing a doped aluminum nitride film on a substrate. In the method, a process chamber is provided; a target comprising an alloy that comprises aluminum and an alloy atomic species is placed in the process chamber. The alloy atomic species has a concentration in the alloy subject to a manufacturing variation. The substrate is placed in the process chamber; and, while supplying nitrogen, a noble gas of a first atomic species, and a noble gas of a second atomic species, different from the first atomic species, to the process chamber, a sputtering operation is performed to transfer target material from the target to the substrate to form the film. A relative flow rate is set between the noble gas of the first atomic species and the noble gas of the second atomic species to form the film with a pre-defined piezoelectric coefficient notwithstanding the manufacturing variation in the concentration of the alloy atomic species.

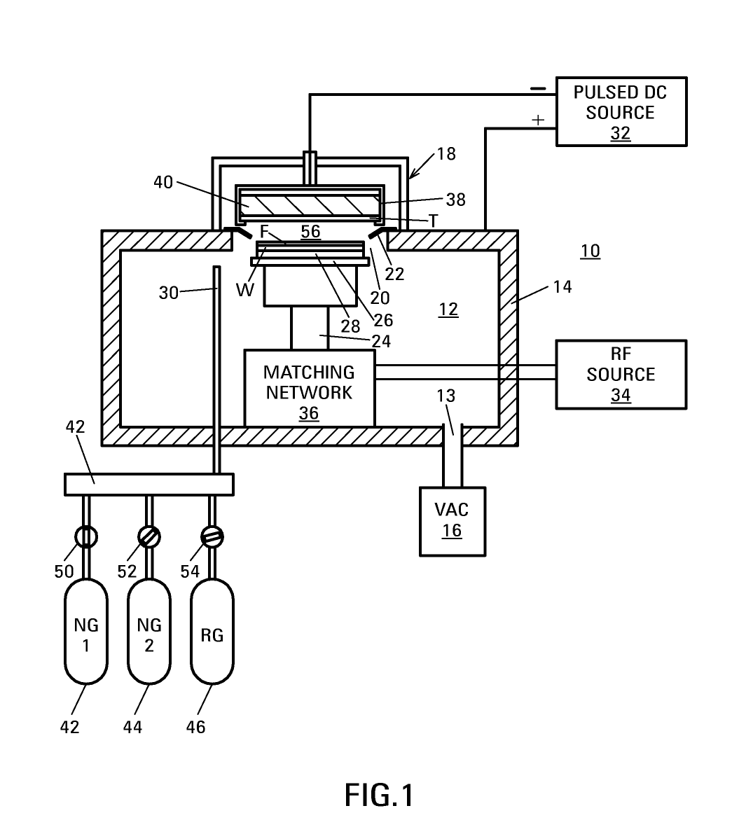

FIG. 1 is a schematic drawing showing an example 10 of a physical vapor deposition (PVD) system that can be used to sputter deposit a piezoelectric film in accordance with this disclosure. Other types of PVD systems are known and may be used. PVD system 10 includes a process chamber 12 bounded by a wall 14. A vacuum pump 16 is in gas communication with process chamber 12 through an aperture 13 in wall 14. A sputter cathode 18 is in gas communication with process chamber 12 through an aperture 20 in wall 14. An annular anode 22 surrounds aperture 20. In the example shown, anode 22 is electrically connected to the wall 14 of process chamber 12, which serves as system ground. A wafer lift 24 is located within process chamber 12 centered on aperture 20. A heating/cooling chuck 26 is mounted on wafer lift 24. Heating/cooling chuck 26 is thermally and electrically coupled to a wafer platform 28. A wafer W on which the piezoelectric film is to be deposited is placed on wafer platform 28 during the deposition method. A wafer W is an example of a substrate on which the piezoelectric film can be deposited by the method disclosed herein. A gas inlet 30 extends through wall 14 to supply gases to process chamber 12. A pulsed DC source 32 is electrically connected between sputter cathode 18 and anode 22. An RF source 34 is electrically connected to wafer lift 24 and, hence, to wafer platform 28, via a matching network 36. Sputter cathode 18 includes a target holder 38 that holds a target T in a position such that the major surface of the target is substantially parallel to wafer platform 28. A magnet system 40 is located between target holder 38 and target T.

Gas inlet 30 is coupled to a manifold 42 to which are connected a source 44 of a noble gas of a first atomic species, a source 46 of a noble gas of a second atomic species, and a source 48 of a reaction gas. For brevity, the noble gas of the first atomic species will be referred to as a first noble gas, and the noble gas of the second atomic species will be referred to as a second noble gas. Each gas source 44, 46, 48 is coupled to manifold 42 via a respective mass flow controller 50, 52, 54. Mass flow controllers 50, 52, 54 control the respective flow rates at which the first noble gas, the second noble gas, and the reaction gas, respectively, are supplied to process chamber 12. In particular, mass flow controllers 50, 52 control the flow rates of the first noble gas and the second noble gas, respectively and, hence, a relative flow rate between the first noble gas and the second noble gas. The relative flow rate between the first noble gas and the second noble gas determines the relative abundances of the first noble gas and the second noble gas in the atmosphere within process chamber 12, and specifically within a gap 56 between target T and wafer W. In another example, the first noble gas and the second noble gas are supplied to process chamber 12 through respective instances of gas inlet 30.

The reaction gas reacts with target material ejected from target T to form the piezoelectric material that is deposited on wafer W. FIG. 1 shows a film F of the piezoelectric material deposited on the major surface of wafer W facing target T. In the example shown, the piezoelectric material of film F is aluminum nitride (AlN) doped with scandium (Sc), and nitrogen gas (N₂) is supplied to process chamber 12 as the reaction gas. In another example, the material of film F is zinc oxide (ZnO) doped with magnesium (Mg) and oxygen gas (O₂) is supplied to process chamber 12 as the reaction gas.

In operation of PVD system 10, wafer lift 24 is lowered to its lowest position and a wafer W is placed on wafer platform 28. Wafer W is an example of a substrate on which a piezoelectric film is deposited. If no target has previously been installed in target holder 38, a target T is installed in the target holder. Wafer lift 24 is then operated to raise wafer W into position adjacent anode 22, where the wafer is separated from target T by gap 56. Heating/cooling chuck 26 is operated to set wafer W to a defined deposition temperature. In an example, the deposition temperature is 200° C. Vacuum pump 16 is operated to reduce the pressure within process chamber 12 to the working pressure of the deposition method, and the first noble gas and the second noble gas are supplied to the process chamber from gas sources 44, 46 via mass flow controllers 50, 52, manifold 42 and gas inlet 30. The settings of mass flow controllers 50, 52 define the relative flow rate between the first noble gas and the second noble gas. A reaction gas is additionally supplied to process chamber 12 from gas source 48 via mass flow controller 54, manifold 42, and gas inlet 30.

In an example in which the piezoelectric material is aluminum nitride, the first noble gas, the second noble gas, and the reaction gas supplied to process chamber 12 from gas sources 44, 46, 48 via mass flow controllers 50, 52, 54, manifold 42, and gas inlet 30 are argon (Ar), krypton (Kr) and nitrogen (N₂). In other examples in which the piezoelectric material is aluminum nitride, the first noble gas and the second noble gas are argon and xenon (Xe), respectively, or krypton and xenon, respectively. Argon and krypton, argon and xenon, or krypton and xenon can also be used as the first noble gas and the second noble gas, respectively, in the method disclosed herein for sputter depositing other piezoelectric materials such as zinc oxide (ZnO). For sputter depositing piezoelectric materials in which at least one of the base metal atomic species and the alloy atomic species has an atomic weight comparable with that of neon (Ne—atomic weight 20), neon can be used as one of the noble gases in the above noble gas combinations.

The magnet system 40 generates a magnetic field in the gap 56 between target T and wafer W. Magnet system 40 is structured to generate the magnetic field with field lines substantially orthogonal to the major surface of target T. RF source 34 applies RF power between wafer platform 28 (and, hence, wafer W) and system ground (and, hence, anode 22). Pulsed DC source 32 applies a DC voltage to sputter cathode 18 relative to system ground and, hence, anode 22 such that the sputter cathode is at a negative voltage relative to the anode. A DC voltage that sets the sputter cathode to a negative voltage relative to the anode will be referred to herein as a normal-polarity DC voltage. The normal-polarity DC voltage causes target T to emit electrons into the gap 56. In an example, the normal-polarity DC voltage is approximately 500 V. In response to the electric field generated by the normal-polarity DC voltage between cathode 18 and anode 22, the electrons move towards wafer W in spirals around the magnetic field lines. The moving electrons collide with the gas atoms in the atmosphere within gap 56. The collisions dislodge electrons from the gas atoms, which converts the gas atoms into positively-charged gas ions. The electric field accelerates the gas ions towards target T. The gas ions incident on target T eject target material from the target. The target material ejected from the target, referred to herein as ejected target material moves towards wafer W and a portion of the ejected target material is deposited on the wafer. While in transit to the wafer, and/or after it has been deposited on the wafer, the ejected target material reacts with the reaction gas constituting part of the atmosphere within gap 56 to form piezoelectric material on the major surface of wafer W. Additionally, a small fraction of the noble gases constituting respective parts of the atmosphere within gap 56 are trapped interstitially within the piezoelectric material.

A large positive charge that tends to repel the positively-charged gas ions accumulates on the target T. To dissipate the accumulated positive charge, pulsed DC source 32 operates repetitively to turn off the DC voltage, to apply a smaller reverse-polarity DC voltage (e.g., about −50 V) between sputter cathode 18 and anode 22, and then to restore the normal-polarity DC voltage. In an example, the duration of the normal-polarity DC voltage is approximately 1 μs and the duration of the reverse-polarity DC voltage is approximately 100 ns. Other voltages and durations are possible and may be used. Additionally, the RF bias applied between wafer W and anode 22 applies a negative DC bias to the wafer that attracts positively-charged ions to bombard the film of target material growing on the wafer to control stress and enhance the mobility of arriving target material.

In another example, an additional RF source (not shown) is substituted for pulsed DC source 32, and material is transferred from target T to wafer W by RF sputter deposition in which the relative flow rate between the noble gas of the first atomic species and the noble gas of the second atomic species is set to form the film of the material with a pre-defined piezoelectric coefficient notwithstanding manufacturing variation in the concentration of the alloy atomic species in the target material. Other sputter deposition processes are known and may be used to transfer material from target T to wafer W by sputter deposition in which the relative flow rate between the noble gas of the first atomic species and the noble gas of the second atomic species is set to form the film of the material with a pre-defined piezoelectric coefficient notwithstanding manufacturing variation in the concentration of the alloy atomic species in the target material.

Deposition of the piezoelectric material continues until piezoelectric film F reaches its specified thickness. During the deposition process, the RF bias applied between wafer W and anode 22 applies a negative DC bias to the wafer that attracts positively-charged ions to bombard the film of target material growing on the wafer to control stress and enhance the mobility of arriving target material. Wafer W with piezoelectric film F on its major surface is then removed from process chamber 12 for further processing, including process operations that form electronic devices, such as diplexers and FBARs, each having a respective portion of piezoelectric film F as an element thereof. Use of the sputter deposition method disclosed herein to form the piezoelectric element of an electronic device is evidenced by the interstitial noble gases of two different atomic species in the piezoelectric element. Such interstitial noble gases can be detected by, for example, subjecting the piezoelectric element to mass spectroscopy.

The method just described is then repeated to sputter deposit respective piezoelectric films on additional wafers. Piezoelectric films can be deposited on several wafers before all the target material constituting target T is consumed. Once this occurs, the remains of target T are removed from target holder 38, and a new target is installed in the target holder.

Due to a manufacturing variation, the concentration of the alloy atomic species in the new target may well be different from that in target T. In this disclosure, the mass of the alloy atomic species in a defined quantity of a material divided by the sum of the masses of the alloy atomic species and the base metal atomic species in the defined quantity of the material will be referred to herein as a concentration of the alloy atomic species in the material. For example, the mass of the alloy atomic species in a defined mass or volume of the target material divided by the sum of the masses of the alloy atomic species and the base metal atomic species in the defined mass or volume of the target material is referred to herein as the concentration of the alloy atomic species in the target material. The concentration of the alloy atomic species (which acts as the dopant) in the piezoelectric material can be similarly defined.

When the concentration of the alloy atomic species in the target material of the new target is different from that of target T, the relative flow rate between the first noble gas and the second noble gas is changed to compensate for the concentration difference between the targets. This compensation makes the concentration of the alloy atomic species in the piezoelectric material deposited using the new target substantially the same as that in the piezoelectric material deposited using target T. The variability in the concentration of the alloy atomic species among the targets may require that the relative flow rate between the noble gases be changed with each new target. Targets having less variability may require that the relative flow rate between the noble gases be changed only between different manufacturing batches of targets.

As noted above, target T is composed of a target material that is a metal alloy that includes a base metal atomic species and an alloy atomic species, the concentration of which in the target material is subject to a manufacturing variation. As noted above, conventional sputter deposition processes lack a mechanism to control the concentration of the alloy atomic species in the piezoelectric material independently of the concentration of the alloy atomic species in the target material. The manufacturing variation in the concentration of the alloy atomic species in the target material can be greater than a tolerable variation in the concentration of the alloy atomic species in the piezoelectric material. In an example, the tolerable variation in the concentration of the alloy atomic species in the piezoelectric material is a concentration range within which the RF properties of devices manufactured from the piezoelectric material meet specification.

In an example in which the piezoelectric material is aluminum nitride doped with scandium, the material of target T is an alloy in which the base metal atomic species is aluminum and the alloy atomic species is scandium. In doped aluminum nitride deposited using a conventional sputter deposition process, the concentration of scandium in the alloy constituting the target material is the primary determinant of the concentration of scandium in the piezoelectric material and, hence, of the piezoelectric coefficient of the piezoelectric material deposited on wafer W. Consequently, manufacturing variations in the concentration of scandium in the target material different targets produce corresponding variations in the concentration of scandium in the piezoelectric material deposited using those targets, and, hence, undesirable manufacturing variations in the piezoelectric coefficient of the piezoelectric material. However, when the piezoelectric material is deposited using the sputter deposition method disclosed herein, the concentration of scandium in the piezoelectric material and, hence, the piezoelectric coefficient of the piezoelectric material, depends not only on the concentration of scandium in the target material but also on the relative flow rate between the first noble gas and the second noble gas. This allows the manufacturing variations in the concentration of scandium among different targets to be compensated for by adjusting the relative flow rate between the noble gases to achieve a specified concentration of scandium in the piezoelectric material and, hence, to deposit piezoelectric material having a specified piezoelectric coefficient. Similar results can be obtained in an example in which the piezoelectric material is zinc oxide doped with magnesium, and in other doped piezoelectric materials. The piezoelectric coefficient of a piezoelectric material is the fractional change in a dimension of the piezoelectric material caused the application of a defined voltage to the material

In the deposition method disclosed herein, target material is deposited on the major surface of wafer W to form film F. However, not all of the target material ejected from the target is deposited on wafer W. While in transit from the target to the wafer, the atoms constituting the ejected target material collide with the gas atoms and ions constituting the atmosphere within gap 56. The collisions scatter the ejected target material moving towards wafer W, which increases the angular spread of the ejected target material. The increased angular spread reduces the fraction of the ejected target material deposited on wafer W. The increase in the angular spread depends on the atomic weight of each atomic species constituting the ejected target material and the atomic weight of each gas constituting the atmosphere within gap 56. That said, since the atomic weight of nitrogen is less than half that of the noble gases constituting the atmosphere within gap 56, the effect of nitrogen on the angular spread of typical atomic species constituting the ejected target material is small compared with that of the noble gases, and will be ignored in the following description. Moreover, in the following description, the constituents of the atmosphere within gap 56 will be referred to as gases even though the gases are typically ionized.

The increase in the angular spread of a given atomic species constituting the ejected target material depends on a ratio between the atomic weight of the target material atomic species and the atomic weight of the gas with which the target material collides. For example, a noble gas within gap 56 having a given atomic weight increases the angular spread of a target material atomic species having a lesser atomic weight more than it increases the angular spread of a target material atomic species having a greater atomic weight. Moreover, a noble gas within gap 56 having a greater atomic weight increases the angular spread of a given target material atomic species by more than a noble gas having a lesser atomic weight.

The process of transferring each atomic species constituting the target material from target T to wafer W can be regarded as being subject to a loss factor that can be defined as a ratio between a mass of the target material atomic species deposited on wafer W during a deposition operation and a mass of the target material atomic species ejected from target T during the deposition operation. In an example in which the target material is composed of a base metal atomic species having atomic weight less than that of the alloy atomic species (e.g., target material in which the base metal atomic species is aluminum (atomic weight (AW)=27) and the alloy atomic species is scandium (AW=45)), the collisions between the ejected target material and the noble gas within gap 56 increase the angular spread of the base metal atoms more than they increase the angular spread of the alloy atoms. Consequently, the loss factor of the base metal atomic species is greater than the loss factor of the alloy atomic species. In an example in which the atomic weight of the base metal atomic species (e.g., zinc (AW=65) is greater than that of the alloy atomic species (e.g., magnesium (AW=24)), the collisions between the ejected target material and the noble gases within gap 56 increase the angular spread of the base metal atomic species less than they increase the angular spread of the alloy atomic species. Consequently, the loss factor of the base metal atomic species is less than the loss factor of the alloy atomic species.

In a conventional sputtering process, the atmosphere within gap 56 includes a noble gas of no more than one atomic species (although the noble gas of no more than one atomic species may include traces of noble gases of other atomic species). In an example in which the atomic weight of the base metal atomic species is less than that of the alloy atomic species, the increase in the angular spread of the base metal atoms is greater than that of the alloy atoms. Consequently, the loss factor of the base metal atomic species is greater than that of the alloy atomic species, so that the concentration of the alloy atomic species in the piezoelectric material is greater than the concentration of the alloy atomic species in the target material. However, since the loss factors are fixed, the main determinant of the concentration of the alloy atomic species in the piezoelectric material is the concentration of the alloy atomic species in the target material.

In the sputter deposition method disclosed herein, the atmosphere within gap 56 includes the first noble gas and the second noble gas. The first noble gas and the second noble gas differ in atomic species. The first noble gas scatters the base metal atoms constituting the target material ejected from the target to a different extent than the second noble gas. The first noble gas scatters the alloy atoms constituting the target material to a different extent than the second noble gas, and to an extent that is different from the extent to which the first noble gas scatters the base metal atoms constituting the target material. Since the extent to which the atoms of a given atomic species are scattered determines the loss factor of that atomic species, the composition of the doped piezoelectric material deposited on the wafer can be controlled by controlling the relative abundance of the noble gases in the atmosphere in gap 56. The relative abundance of the noble gases is controlled by controlling the relative flow rate between the first noble gas and the second noble gas as the noble gases are input to process chamber 12.

In an example in which the atomic weight of the base metal atomic species is less than that of the alloy atomic species, both the first noble gas and the second noble gas increase the angular spread of the base metal atoms (and, hence, the loss factor of the base metal atomic species) more than they increase the angular spread of the alloy atoms (and, hence, the loss factor of the alloy atomic species), but the noble gas having the greater atomic weight increases the angular spreads of both the base metal atoms and the alloy atoms by more than the noble gas having the lesser atomic weight. Consequently, increasing the abundance of the noble gas having the greater atomic weight in the atmosphere within gap 56 will increase the angular spread of the base metal atoms more than it increases the angular spread of the alloy atoms. The effect of increasing the abundance of the noble gas having the greater atomic weight is to increase the loss factor of the base metal atomic species by more than the loss factor of the alloy atomic species is increased, which increases the concentration of the alloy atomic species in the doped piezoelectric material deposited on wafer W. In an example in which the atomic weight of the base metal atomic species is more than that of the alloy atomic species, the effect of increasing the abundance of the noble gas having the greater atomic weight in the atmosphere within gap 56 is the opposite of that described.

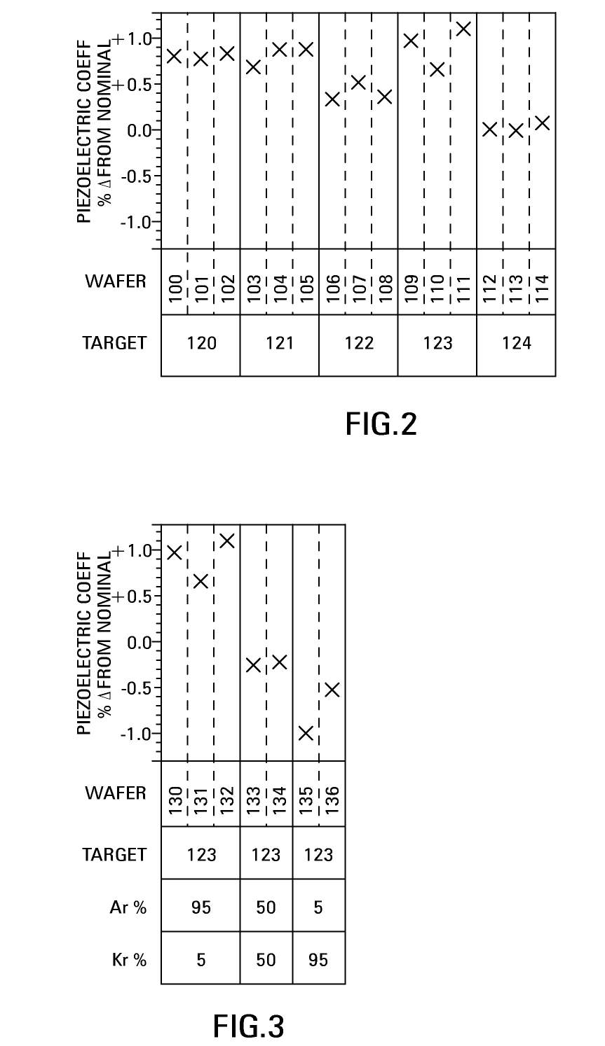

The sputter deposition method disclosed herein can be designed to deposit film F of piezoelectric material with a specified concentration of the alloy atomic species therein from a first target having a nominal concentration of the alloy atomic species in the target material using a nominal relative flow rate between the first noble gas and the second noble gas. Then, when the deposition method is performed using a second target in which a manufacturing variation results in a lower-than-nominal concentration of the alloy atomic species in the target material, the relative flow rate between the first noble gas and the second noble gas is changed in a way that decreases the loss factor of the alloy atomic species and/or increases the loss factor of the base metal atomic species such that film F of piezoelectric material is deposited with the specified concentration of the alloy atomic species. Changing the relative flow rate between the noble gases makes the electrical properties of devices manufactured from the piezoelectric film deposited using the second target more similar to those of devices made from the piezoelectric film deposited using the first target than if the piezoelectric films were deposited using a single noble gas. FIG. 2 is a chart showing examples of the piezoelectric coefficients of doped aluminum nitride films, conventionally deposited using six exemplary targets. The piezoelectric coefficients are expressed in terms of a percentage difference from a nominal piezoelectric coefficient. The target material of each of the targets was an alloy of a base metal atomic species, aluminum, and an alloy atomic species, scandium. Manufacturing variations resulted in variations among the targets in the concentration of scandium in the alloy. In all the depositions, the atmosphere in the gap between the target and the wafer included no more than one noble gas, specifically, argon. Respective doped aluminum nitride films were deposited on three different wafers using each target. Specifically, a target 120 was used to deposit respective doped aluminum nitride films on wafers 100-102, a target 121 was used to deposit respective doped aluminum nitride films on wafers 103-105, a target 122 was used to deposit respective doped aluminum nitride films on wafers 106-108, a target 123 was used to deposit respective doped aluminum nitride films on wafers 109-111, and a target 124 was used to deposit respective doped aluminum nitride films on wafers 112-114. Piezoelectric coefficients were measured in various locations of the doped aluminum nitride film on each of the wafers, and the measurement results for each wafer were averaged. The percentage difference between the average piezoelectric coefficient for each combination of wafer and target and the nominal piezoelectric coefficient is shown in the chart by a respective X. In the example shown, the percentage differences between the average measured piezoelectric coefficients range and the nominal piezoelectric coefficient from about 1.1% (wafer 111, target 123) to about 0.0% (wafer 113, target 124).

FIG. 3 is a chart showing an example of a range over which the piezoelectric coefficients of doped aluminum nitride films can be changed by varying the relative flow rate between two noble gases in the sputter deposition method disclosed herein. In this example, a single target was used in the deposition method and the relative flow rate between a first noble gas, argon, and a second noble gas, krypton, was varied. The target used to obtain the results shown was target 123, which was also used to generate one set of the examples shown in FIG. 2. Target 123 was used to deposit respective doped aluminum nitride films on wafers 130-132 with an argon flow rate of 95% and a krypton flow rate of 5%. Target 123 was additionally used to deposit respective doped aluminum nitride films on wafers 133, 134 with an argon flow rate of 50% and a krypton flow rate of 50%. Finally, target 123 was additionally used to deposit respective doped aluminum nitride films on wafers 135, 136 with an argon flow rate of 5% and a krypton flow rate of 95%. Piezoelectric coefficients were measured in various locations of the doped aluminum nitride film on each of the wafers, and the measurement results for each wafer were averaged. The percentage difference between the average piezoelectric coefficient for each combination of wafer, target and flow rates of the noble gases and the nominal piezoelectric coefficient is shown in the chart by a respective X. In the example shown, the percentage differences between the average measured piezoelectric coefficients and the nominal piezoelectric coefficient ranges from about +1.2% (wafer 132, target 123, 95% Ar, 5% Kr) to about −1.0% (wafer 135, target 123, 5% Ar, 95% Kr). These results indicate that the range of piezoelectric coefficients that can be obtained by varying the relative flow rate between the two noble gases is substantially larger than the range of piezoelectric coefficients resulting from manufacturing variations in the concentration of the alloy atomic species in the exemplary targets shown in FIG. 2. Thus the relative flow rate between the noble gases can be varied to reduce the effect of manufacturing variations in the concentration of the alloy atomic species in the targets on the concentration of the alloy atomic species in the deposited films.

A methodology similar to that just described can be used to calibrate the sputter deposition method disclosed herein. A nominal piezoelectric coefficient for piezoelectric films deposited using the deposition method is initially defined. Then, a calibration process is performed for each target prior to using the target in the deposition method. Using each target, respective test depositions are made on one or more wafers with respective different relative flow rates between the two noble gases. In an example, the three different relative flow rates exemplified in FIG. 3 are used. The piezoelectric coefficient of the piezoelectric film deposited on each of the wafers is then measured. A process such as interpolation or a lookup table is then used to determine a relative flow rate between the two noble gases that, when used with the target in the sputter deposition method disclosed herein, will result in the deposition of piezoelectric films having a piezoelectric coefficient close to the above-described nominal piezoelectric coefficient.

In another calibration process, the concentration of the alloy atomic species in a number of representative targets is measured, and a piezoelectric film is deposited on a respective wafer using each of the targets. The depositions are all carried out using the same relative flow rate between the first noble gas and the second noble gas, or even using a single noble gas. The piezoelectric coefficient of the piezoelectric film deposited on each of the wafers is then measured and is linked to the measured concentration of the alloy atomic species in the target used in the deposition method. Additionally, using those of the targets that represent the extremes and the center of the range of measured concentrations of the alloy atomic species, test depositions are made on respective wafers with respective different relative flow rates between the two noble gases. The piezoelectric coefficient of the piezoelectric film on each of the wafers is then measured and is linked to the relative flow rate between the two noble gases. The data generated from the test depositions are then used to generate a mathematical model that links a measured concentration of the alloy atomic species in a given target to a relative flow rate between two noble gases that will result in the deposition of a piezoelectric film having a piezoelectric coefficient close to the nominal piezoelectric constant using the target.

Prior to a target being used in the sputter deposition method disclosed herein, the concentration of the alloy atomic species the target is measured, and the measurement result is input to the mathematical model. In response to the input, the mathematical model outputs the relative flow rate between the two noble gases needed to deposit piezoelectric material having the nominal piezoelectric coefficient using the target. Referring to FIG. 1, the target is then placed in target holder 38, mass flow controllers 50, 52 are set manually or automatically to provide the relative flow rate between the two noble gases indicated by the mathematical model, and piezoelectric film F is deposited on wafer W using the target.

The mathematical model can be in the form of an equation, a lookup table, a graph, a computer program, or another suitable type of mathematical model that enables the relative flow rate between the two noble gases to be determined for each target without the need to deposit a test film using the target and to measure the piezoelectric coefficient of the test film. In some instances, the concentration of the alloy atomic species in the target is measured by the manufacturer of the target and is provided to the user of the target in a suitable form. In an example, the concentration is represented by a barcode affixed to the target. In another example, respective concentrations for the targets constituting a batch of targets are electronically stored in a table linked to respective serial numbers of the targets. Prior to the targets being used in the deposition method, the serial number of each target is electronically read, the respective concentration for the target is retrieved from the table, and is used to set the relative flow rate between the first noble gas and the second noble gas.

The concentration of the alloy atomic species in the target can be measured using measurement techniques such as, but not limited to, inductively coupled plasma mass spectroscopy (ICPMS), surface ion mass spectroscopy (SIMS), Rutherford back scattering (RBS), electron spectroscopy for chemical analysis (ESCA), x-ray fluorescence (XRF), and auger electron spectroscopy (AES) may be used to measure. Other techniques capable of measuring the concentration of an atomic species and an alloy with a resolution of the order of 1/10 of 1% are known and may be used.

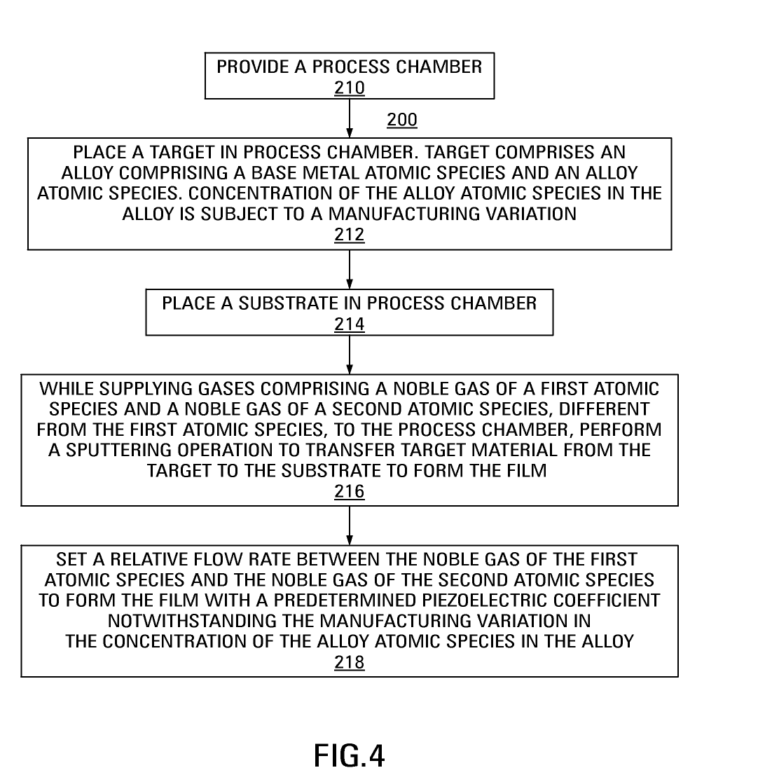

FIG. 4 is a flowchart showing an example 200 of a method as disclosed herein for sputter depositing a doped piezoelectric film on a substrate. In block 210, a process chamber is provided. In block 212, a target is placed in the process chamber. The target comprises an alloy that comprises a base metal atomic species and an alloy atomic species. The concentration of the alloy atomic species in the alloy is subject to a manufacturing variation. In block 214, the substrate is placed in the process chamber. In an example, a wafer is used as the substrate.

In block 216, while supplying gases comprising a noble gas of a first atomic species and a noble gas of a second atomic species, different from the first atomic species, to the process chamber, a sputtering operation is performed to transfer target material from the target to the substrate to form the film.

In block 218, a relative flow rate between the noble gas of the first atomic species and the noble gas of the second atomic species is set to form the film with a predetermined piezoelectric coefficient notwithstanding the manufacturing variation in the concentration of the alloy atomic species in the alloy.

In an embodiment of method 200 is for depositing a doped aluminum nitride film on a substrate, in block 212, the target comprises an alloy that comprises aluminum and an alloy atomic species. The alloy atomic species has a concentration in the alloy subject to a manufacturing variation. In block 216, while nitrogen, a noble gas of a first atomic species and a noble gas of a second atomic species, different from the first atomic species, are supplied to the process chamber, the sputtering operation is performed to transfer target material from the target to the substrate to form the film. In block 218, a relative flow rate between the noble gas of the first atomic species and the noble gas of the second atomic species to form the film with a pre-defined piezoelectric coefficient notwithstanding the manufacturing variation in the concentration of the alloy atomic species in the alloy.

In an embodiment, in block 216, the sputtering operation is performed by performing pulsed DC sputtering or RF sputtering.

In an embodiment, in block 216, the noble gas of the first atomic species is argon.

In an embodiment, in block 216, the noble gas of the first atomic species is argon, and the noble gas of the second atomic species is one of neon, krypton, and xenon.

In an embodiment, in block 216, the noble gas of the first atomic species is krypton.

In an embodiment, in block 216, the noble gas of the first atomic species is krypton, and the noble gas of the second atomic species is one of neon, argon, and xenon.

In an embodiment, method 200 additionally comprises generating calibration data for the target, and, in block 218, the relative flow rate between the noble gases is set in accordance with the calibration data.

In an embodiment, method 200 additionally comprises generating calibration data for the target; in block 218, the relative flow rate between the noble gases is set in accordance with the calibration data, and the calibration data for the target is generated by a process that comprises measuring a concentration of the alloy atomic species in the target to generate at least part of the calibration data.

In an embodiment, method 200 additionally comprises generating calibration data for the target using a process that comprises using the target to deposit at least one test film of doped piezoelectric material with a respective defined relative flow rate between the noble gas of the first atomic species and the noble gas of the second atomic species, and measuring a piezoelectric coefficient of the at least one test film to generate at least part of the calibration data. Then, in block 216, the relative flow rate between the noble gases is set in accordance with the calibration data.

In an embodiment, in block 212, the base metal atomic species is aluminum and the alloy atomic species is scandium.

In an embodiment, in block 212, the base metal atomic species is zinc and the alloy atomic species is magnesium.

This disclosure describes the invention in detail using illustrative embodiments. However, the invention defined by the appended claims is not limited to the precise embodiments described.

We claim:

1. A method of sputter depositing a doped aluminum nitride film on a substrate, the method comprising:
providing a process chamber;
placing a target in the process chamber, the target comprising an alloy comprising aluminum and an alloy atomic species, the alloy atomic species having a concentration in the alloy subject to a manufacturing variation;
placing the substrate in the process chamber; and
while supplying nitrogen, a noble gas of a first atomic species and a noble gas of a second atomic species, different from the first atomic species, to the process chamber, performing a sputtering operation to transfer target material from the target to the substrate to form the film; and
setting a relative flow rate between the noble gas of the first atomic species and the noble gas of the second atomic species to form the film with a pre-defined piezoelectric coefficient notwithstanding the manufacturing variation in the concentration of the alloy atomic species in the alloy.

2. The method of claim 1, in which the performing comprises performing one of pulsed DC sputtering and RF sputtering.

3. The method of claim 1, in which the noble gas of the first atomic species is argon.

4. The method of claim 3, in which the noble gas of the second atomic species is one of neon, krypton, and xenon.

5. The method of claim 1, in which the noble gas of the first atomic species is krypton.

6. The method of claim 5, in which the noble gas of the second atomic species is one of neon, argon, and xenon.

7. The method of claim 1, in which:
the method additionally comprises generating calibration data for the target; and
the setting comprises setting the relative flow rate in accordance with the calibration data.

8. The method of claim 7, in which the generating comprises measuring a concentration of the alloy atomic species in the target to generate at least part of the calibration data.

9. The method of claim 7, in which the generating comprises:
using the target to deposit at least one test film of doped aluminum nitride with a respective defined relative flow rate between the noble gas of the first atomic species and the noble gas of the second atomic species; and
measuring a piezoelectric coefficient of the at least one test film to generate at least part of the calibration data.

10. A method of sputter depositing a doped piezoelectric film on a substrate, the method comprising:
providing a process chamber;
placing a target in the process chamber, the target comprising an alloy comprising a base metal atomic species and an alloy atomic species, in which a concentration of the alloy atomic species in the alloy is subject to a manufacturing variation;
placing the substrate in the process chamber;
while supplying gases comprising a noble gas of a first atomic species and a noble gas of a second atomic species, different from the first atomic species, to the process chamber, performing a sputtering operation to transfer target material from the target to the substrate to form the film; and
setting a relative flow rate between the noble gas of the first atomic species and the noble gas of the second atomic species to form the film with a predetermined piezoelectric coefficient notwithstanding the manufacturing variation in the concentration of the alloy atomic species in the alloy.

11. The method of claim 10, in which the performing comprises performing one of pulsed DC sputtering and RF sputtering.

12. The method of claim 10, in which the noble gas of the first atomic species is argon.

13. The method of claim 12, in which the noble gas of the second atomic species is one of neon, krypton, and xenon.

14. The method of claim 10, in which the noble gas of the first atomic species is krypton.

15. The method of claim 14, in which the noble gas of the second atomic species is one of neon, argon, and xenon.

16. The method of claim 10, in which:
the method additionally comprises generating calibration data for the target; and
the setting comprises setting the relative flow rate in accordance with the calibration data.

17. The method of claim 16, in which the generating comprises measuring a concentration of an alloy atomic species in the target to generate at least part of the calibration data.

18. The method of claim 16, in which the generating comprises:
using the target to deposit at least one test film of doped piezoelectric material with a respective defined relative flow rate between the noble gas of the first atomic species and the noble gas of the second atomic species; and
measuring a piezoelectric coefficient of the at least one test film to generate at least part of the calibration data.

19. The method of claim 10, in which the base metal atomic species is aluminum and the alloy atomic species is scandium.

20. The method of claim 10, in which the base metal atomic species is zinc and the alloy atomic species is magnesium.

21. An electronic device, comprising a piezoelectric film comprising interstitial noble gas of two or more different atomic species.
